(19) United States
(12) Patent Application Publication
(10) Pub. No.: US 2007/0072330 A1
(43) Pub. Date: Mar. 29, 2007

(54) Wafer bonding compatible with bulk micro-machining

(75) Inventors: Dan O. Popa, Euless, TX (US); Byoung Hun Kang, Troy, NY (US); Jian-Qiang Lu, Troy, NY (US); Taejoo Hwang, Troy, NY (US); Eric M. Leonard, Rochester, NY (US); Harry E. Stephanou, Niskayuna, NY (US)

Correspondence Address: WOLF GREENFIELD & SACKS, PC, FEDERAL RESERVE PLAZA, 600 ATLANTIC AVENUE, BOSTON, MA, 02210-2206, US

(73) Assignee: Rensselaer Polytechnic Institute, Troy, NY (US)

(21) Appl. No.: 10/548,134

(22) PCT Filed: Mar. 5, 2004
(86) PCT No.: PCT/US04/06826

§ 371 Date: Nov. 15, 2006

Related U.S. Application Data
(60) Provisional application No. 60/452,347, filed on Mar. 5, 2003.
(60) Provisional application No. 60/538,611, filed on Jan. 23, 2004.

(51) Int. Cl. H01L 21/00

(52) U.S. Cl. 438/53; 438/52; 438/48

(57) ABSTRACT

A method for forming a microstructure is disclosed in which, after a polymer substance has been applied to a first substrate, the first substrate is micromachined to remove at least one portion of the first substrate. A second substrate is then adhered to the first substrate via the polymer substance. One application of such a method is in the fabrication of three-dimensional microfluidics. The polymer substance may, for example, be benzocyclobutene (BCB), and the first substrate may, for example, be a silicon wafer or a photo-etchable glass.

This application claims the benefit of each of the following U.S. provisional patent applications: (1) Ser. No. 60/452,347, filed Mar. 5, 2003, entitled “Formation of micro-channels by patterning of BCB, bulk micro-machining and wafer bonding,” and (2) Ser. No. 60/538,611, filed Jan. 23, 2004, entitled “BCB Wafer Bonding.”

### FIELD OF THE INVENTION

The present invention is directed to the bonding of wafers to form microstructures.

### BACKGROUND

Wafer-to-wafer bonding as a mature technology in microelectronics is increasingly relevant for high volume and zero-level packaging of Micro-Electro-Mechanical System (MEMS) devices and microfluidics. Anodic and fusion bonding of silicon and glass wafers are known to provide very strong, hermetic wafer bonds, but with very strict requirements for surface preparation and process conditions. In addition, the range of processing temperatures and voltages limits the use of these two bonding techniques in some applications.

The combination of wet or dry bulk etching and anodic/fusion bonding is known method for fabricating biocompatible microfluidic channels in glass and silicon. In the case of glass, however, its isotropic etching characteristics in hydrofluoric acid (HF) solution makes it difficult to construct high-aspect ratio microchannels and etch-through holes with good vertical sidewall definition. The HF solution also attacks the bonding surface of glass and therefore increases its roughness. As a result, HF-etched glass wafers can be unsuitable for anodic and fusion bonding without optimizing the etching process.

Anodic bonding requires very low surface roughness (˜20 nm) and high electrostatic field (100˜1 kV), which can damage sensitive devices and bond unwanted wafer areas. Fusion bonding is usually performed at high temperatures (˜1000° C.) that most polymer materials cannot withstand.

Microchannels can also be fabricated using polymers such as poly-dimethylsiloxane (PDMS) by micromolding at relatively modest process temperatures. Complex microfluidic structures, such as through-holes and 3D interconnects, can be fabricated using polymers with good biocompatibility. But these materials have lower mechanical strength than silicon or glass, and they are not CMOS compatible.

Wafer bonding using dielectric polymers, such as PI-2610, S1818, and, more, recently, benzocyclobutene (BCB) has been proposed for stacking IC wafers in three-dimensional (3D) electronics. Such proposed techniques are described, for example, in (1) Niklaus, F., Enoksson, P., Kalvesten, E., and Stemme, G., 2001, “Low-temperature full wafer adhesive bonding,” Journal of Micromechanics and Microengineering 11, no. 2, (2) Niklaus, F., Enoksson, P., Kalvesten, E., and Stemme, G., 2000, “Void-Free Full Wafer Adhesive Bonding,” 13th IEEE Int. Conference on MicroElectroMechanical Sytems (MEMS'00) Miyazahci, Japan, Jan. 23-27, 2000, pp. 247-252, (3) Niklaus, F., Enoksson, P., Griss, P., Kalvesten, E., and Stemme, G., 2001, “Low temperature Wafer-Level Transfer Bonding,” J. of Microelectromechanical systems, Vol. 10, NO. 4, pp. 525-531, (4) T. Matsumoto, M. Satoh, et. al., “New Three-Dimensional Wafer Bonding Technology Using the Adhesive Injection Method,” Jpn. Journal of Applied Physics, 37, pp. 1217-1221, 1998, and (5) T.-K. Chou and K. Najafi, “3D MEMS Fabrication Using Low-Temperature Wafer Bonding With Benzocyclobutene (BCB),” Transducers 2001, Eurosensors XV, pp. 1570-1573, 2001, each of which is incorporated herein by reference in its entirety.

As noted in the foregoing references, the properties of BCB—excellent mechanical strength, very low outgassing, less sensitivity to surface preparation, low cost, low dielectric constant, low cure temperature (as low as 180° C.), high optical transparency, high thermal stability (T_{g}>350° C.), and high solvent resistance, make it a very attractive polymer for wafer bonding.

As explained in F. Niklaus, H. Andersson, et. al., “Low temperature full wafer adhesive bonding of structured wafers,” Sensors and Actuators, A92, pp. 235-241, 2001, and Rebecca J Jackman, Tamara M Floyd, et. al., “Microfluidic systems with on-line UV detection fabricated in photodefinable epoxy,” J. of Micromech. & Microeng., 11, pp. 1-8, 2001, however, compared to fusion and anodic bonding, adhesive bonding has two critical disadvantages for microfluidic applications: one is that it requires at least one flat wafer (for spin-coating the adhesive layer), and the other is that microchannels can be clogged by overflowing adhesive.

In the case of many types of polymer-bonded MEMS wafers, such as those forming microfluidic channels, there are inherent limitations in the way the polymer may be delivered to the interface, since traditional spin-coating methods cannot be directly employed. One way microchannels can be formed with such wafers without spin-coating is through the use of the stamping method, which is described in Niklaus, F., Enoksson, P., Griss, P., Kalvesten, E., and Stemme, G., 2001, “Low temperature Wafer-Level Transfer Bonding,” J. of Microelectromechanical systems, Vol. 10, NO. 4, pp. 525-531. Although this method allows for the transfer of adhesive from a flat surface to the mesa structures of a patterned wafer, the adhesion between polymer and the Si wafer cannot be precisely controlled.

Analysis of bonding quality is an important area in wafer bonding research and many tests have been proposed, such as peel testing, crack opening test, double cantilever beam (DCB) test and 4-point bending test. Such analysis and tests are described, for example, in (1) Den Besten, C., van Hal, R. E. G., Munoz, J., and Bergveld, P., 1992, “Polymer bonding of micro-machined silicon structures,” Proceedings. IEEE Micro Electro Mechanical Systems. An Investigation of Micro Structures, Sensors, Actuators, Machines and Robots, New York, N.Y., USA: IEEE, xv+237, pp. 104-109, (2) Lu, J.-Q., Kwon, Y., Rajagopalan, G., Gupta, M., McMahon, J., Lee, K-W., Kraft, P. R., McDonald, J. F., Cale, T. S., Gutmann, R. J., Xu, B., Eisenbraun, E., Castracane, J., and Kaloyeros, A., 2002, “A Wafer-Scale 3D IC Technology Platform using Dielectric Bonding Glues and Copper Damascene Patterned Inter-Wafer Interconnects,” Proceedings of 2002 IEEE International Interconnect Technology Conference (IITC), San Francisco, Calif., Jun. 3-5, 2002, pp. 78-80, (3) Blom, M. T., Tas, N. R., Pandraud, G., Chmela, E., Gardeniers, J. G. E., Tijssen, R., Elwenspoek, M., and van den Berg, A., 2001, “Failure mechanisms of pressurized microchannels: model and experiments,” Journal of Microelectromechanical Systems 10, no. 1, pp. 158-164, (4) Tong, Q., Y., and Gosele, U., 1999, “Semiconductor wafer bonding: science and technology,” John Wiley & sons, New York, and (5) Satoh, A., 1999, “Water-glass Bonding,” Sensors and Actuators, A72, pp. 160-168, each of which is incorporated herein by reference in its entirety.

As described in (1) Hohlfelder, R. J., Maidenberg, D. A., and Dauskardt, R. H., 2001, “Adhesion of Benzocyclobutene-passivated silicon in epoxy layered structures,” J. Master. Res., Vol. 16, No. 1, pp. 243˜255, (2) Snodgrass, J. M., Pantelidis, D., Jenkins, M. L., Bravman, J. C., and Dauskardt, R. H., 2002, “Subcritical debonding of polymer/silica interfaces under monotonic and cyclic loading,” Acta Materialia 50, no. 9, (24 May 2002), pp. 2395-2411, and (3) Dauskardt, R. H., Lane, M., Ma, Q., and Krishna N., 1998, “Adhesion and debonding of multi-layer thin film structures,” Engineering Fracture Mechanics 61, 1998, pp. 141-162, each of which is incorporated herein by reference in its entirety, the adhesion strength of BCB/SiNₓ and BCB/SiO₂ may be referred to in terms of measured interface fracture energy.

### SUMMARY

According to one aspect of the present invention, a method for forming a microstructure involves applying a polymer substance to a first substrate, and subsequently micromachining the first substrate to remove at least one portion of the first substrate. A second substrate may then be adhered to the first substrate via the polymer substance.

The first and second substrates may, for example, comprise silicon and/or glass wafers, and the polymer substance may, for example, comprise BCB. In some embodiments, the BCB may be used as a mask during etching of the first substrate.

### BRIEF DESCRIPTION OF THE DRAWINGS

FIG. 1 is a flow chart illustrating various method steps that may be employed to create a bulk micro-machined structure with a BCB layer in accordance with an illustrative embodiment of the invention;

FIG. 2 shows cross-sectional views of a structure at various stages during the process shown in FIG. 1;

FIG. 3 is a graph showing a cure contour plot for hot plate curing of BCB;

FIG. 4 shows cross-sectional views similar to those shown in FIG. 2, but in which layer thicknesses are indicated;

FIG. 5 is a diagram illustrating measurements for selectivity and etch rate for BCB and photoresist (PR) layers;

FIG. 6 is a bar graph illustrating measured etch rates for PR and BCB for various O2/CF4 gas compositions;

FIG. 7 is a bar graph showing selectivity ratios between BCB and PR for various O2/CF4 compositions;

FIGS. 8, 9, and 10 are photographs illustrating how inadequate adhesion between BCB and the substrate may cause delamination of BCB film when a KOH solution is used for etching;

FIG. 11 is a diagram illustrating a delamination mechanism which was observed between the BCB and silicon surfaces during KOH etching;

FIGS. 12-16 are photographs showing how various samples identified in Table 1 (below) behaved under particular processing conditions;

FIGS. 17 and 18 are a photograph and a diagram, respectively, illustrating bonding characteristics between various inter-bonded layers;

FIG. 19 is a diagram showing an illustrative example of a 3D microfluidic circuit that may be fabricated using silicon and glass waters that have been BCB bonded and micromachined in accordance with aspects of the invention;

FIG. 20 is a flow chart illustrating various method steps that may be employed to micro-machine a silicon wafer, after applying a BCB bonding layer, using dry etching techniques;

FIG. 21 shows cross-sectional views of a structure at different stages during the process shown in FIG. 20;

FIG. 22 is an annotated photograph illustrating the excellent feature resolution for microfluidic channels that may be obtained after DRIE and photoresist stripping on BCB;

FIGS. 23a-e an example of a process of structuring FORTURAN glass that may be employed in connection with some embodiments of the invention;

FIG. 24 is a flow chart illustrating an example of a method for bonding wafers that may be employed in accordance with some embodiments of the invention;

FIGS. 25a-b are photographs of samples prepared by hard-cured BCB bonding at 2 bars and 4 bars, respectively;

FIGS. 26a-b are photographs of samples prepared by hard-cured BCB bonding at 8 bars and soft-cured BCB bonding at 2 bars, respectively; and

FIG. 27 is a photograph illustrating how soft-cured BCB may reflow over the microstructure edge so as to cause clogging of microchannels.

### DETAILED DESCRIPTION

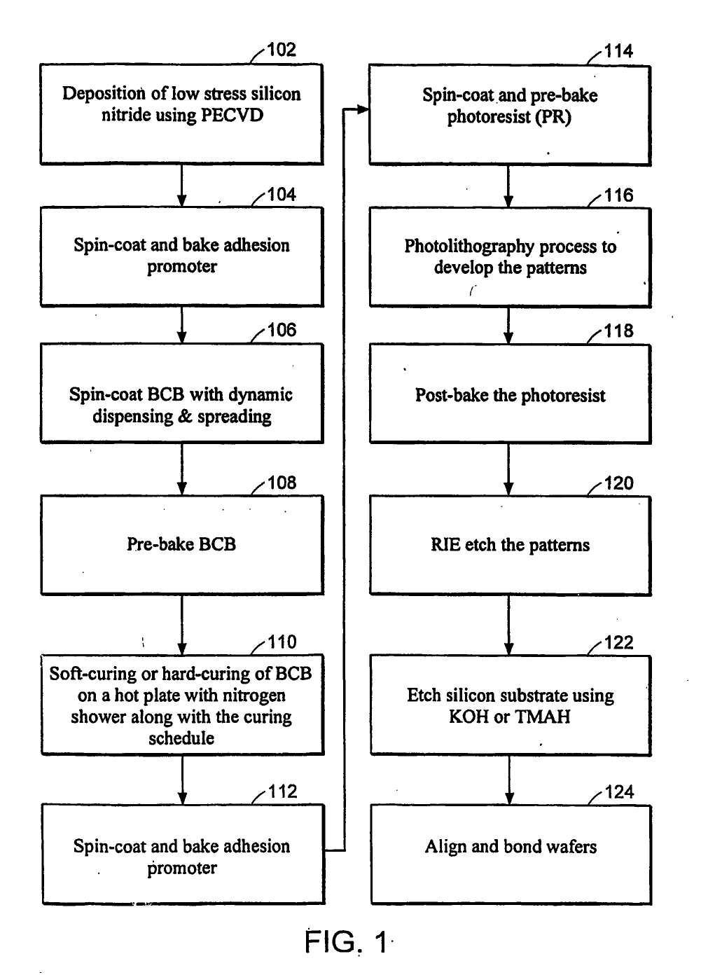

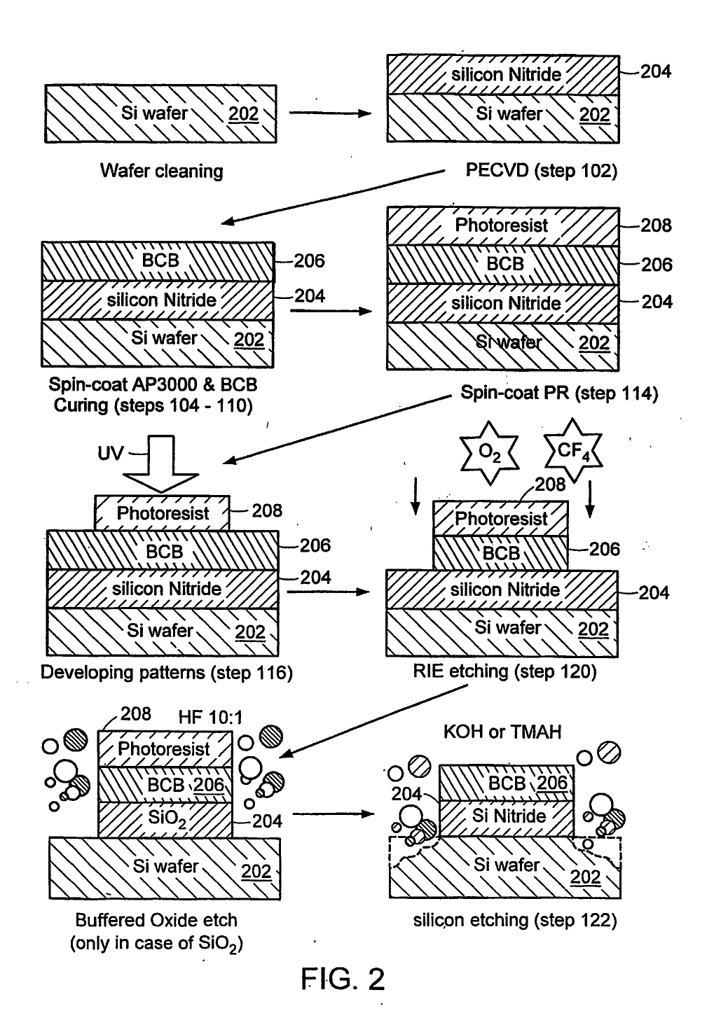

FIG. 1 is a flow chart illustrating various method steps that may be employed to create a bulk micro-machined structure with a BCB layer in accordance with an illustrative embodiment of the invention. FIG. 2 shows cross-sectional views of such a structure at various stages during the process. The following description of the method of FIG. 1 will therefore reference the components shown in FIG. 2, as appropriate.

As shown, after a silicon wafer 202 has been cleaned, a layer of oxide or nitride 204 may be deposited on the silicon wafer 202 (step 102). For example, a low stress silicon nitride ((SiNx)) 204 may be deposited using plasma-enhanced chemical vapor deposition (PECVD). An adhesion promoter (not shown in FIG. 2), for example, AP3000, may then be spin-coated over the oxide or nitride layer 204 and baked (step 104).

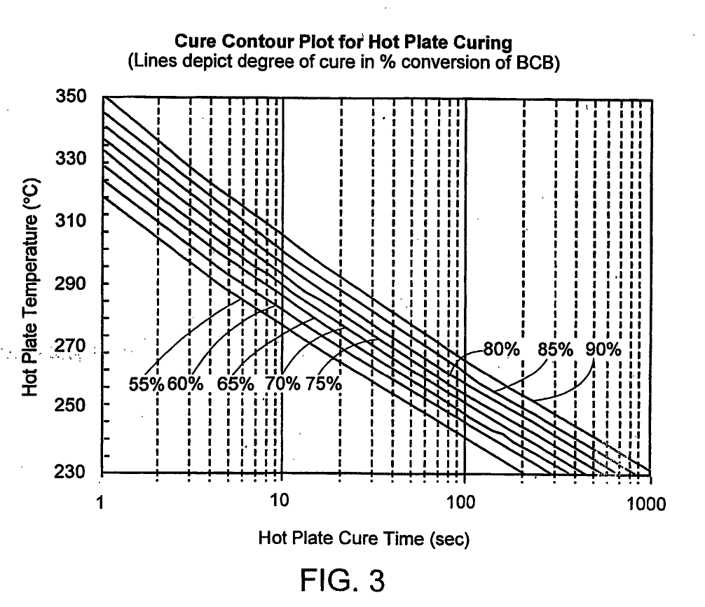

A BCB layer 206 may then be spin-coated onto the oxide or nitride layer 204 (step 106), pre-baked (step 108), and soft or hard cured (step 110). The BCB 206 may, for example, be spin-coated using dynamic dispensing and spreading, and may cured on a hot plate with a nitrogen shower in accordance with a curing schedule such as that shown in FIG. 3.

Another layer of the adhesion promoter (also not shown in FIG. 2) may then be spin-coated onto the BCB layer 206 and baked (step 112), and a photoresist (PR) layer 208 may be spin-coated over the adhesion promoter and pre-baked (step 114).

The BCB layer 206 may then be patterned using conventional photolithography (steps 116-118), and plasma etching (step 120), such as reactive ion etching (RIE). When an SiNx layer 204 is used, it may be also be removed by dry-etching. When a silicone oxide (SiO₂) layer 204 is used, a buffered oxide etching step (not shown in FIG. 1) may then be performed to remove the oxide and expose the bulk wafer 202 for wet etching.

The silicon wafer 202 may then be wet etched using a potassium hydroxide (KOH) or tetra methyl ammonium hydroxide (TMAH) solution (step 122). Finally, the silicon wafer 202 may be aligned with another wafer (not shown) and bonded to it via the BCB layer 206 (step 124).

Satisfactory adhesion of BCB to bare silicon, or to nitride and oxide layers, may be obtained by pre and post baking of adhesion promoters. Adhesion promoters may be used at each interface. It should be appreciated that the weakest interface may not be the BCB to BCB cross-link, but the adhesion between the BCB layer 206 and the hard mask 204 (e.g., SiO₂ or SiNₓ).

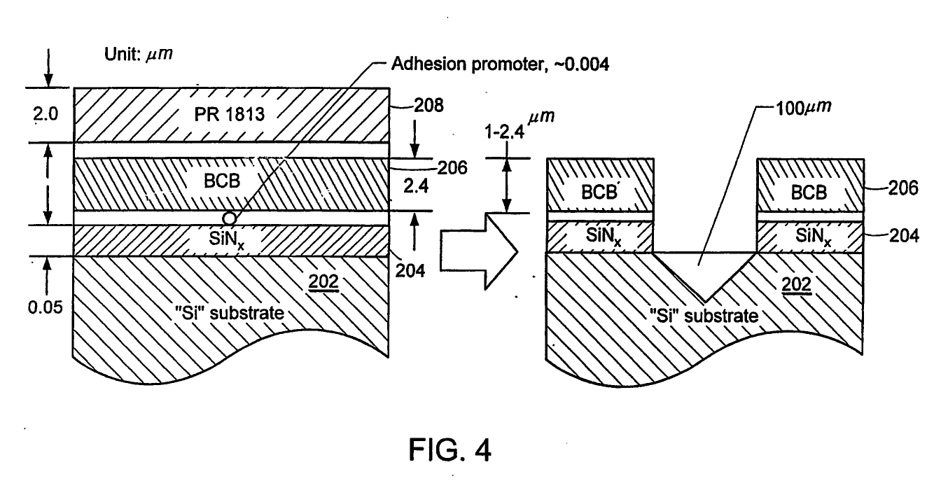

As noted above, after the photoresist pattern has been developed, the pattern may be transferred to the BCB layer 206 by RIE etching. Because both BCB and PR will be etched together during this step, the process parameters such as power, fluorine gas component ratio and pressure should be selected in order to match the etch rates. Inappropriate settings for these parameters can lead to severe BCB layer loss and decrease in bond strength. Considering that the BCB layer 206 will be thinned by both the dry and wet etching processes, the layer thicknesses shown in FIG. 4 were found to be adequate for bonding wafers with channels at least 100 micrometers (μm) deep.

To determine appropriate parameters for etching, BCB:PR etch selectivity experiments were performed. Soft masking using AZP 4620 photoresist has been previously investigated and is described in Berry, M. J., Garrou, P., Rogers, B., and Turlik, I., 1994, “Soft Mask for Via Patterning in BCB Dielectric,” Int. J. Microcircuits & Electronic Packaging, Vol. 17, 1994, pp. 210-218. In our case, we performed selectivity experiments on Shipley 1813 photoresist and cyclotene 3022-46 BCB.

We prepared two sets of samples for measuring the relative step size between the PR 208 and BCB layers 206. One sample had only PR on the substrate and the other had both PR and partially or fully cured BCB processed according to our recipe. The two samples were RIE-etched at the same time for 2 minutes and the film thickness was measured using an Alpha step surface profiler. We varied the relative ratio of gas components between oxygen (O₂) and tetraflouromethane (CF₄) because the selectivity and etch rate are highly dependent on this ratio. The rest of the processing parameters were the same as recommended by the manufacturer.

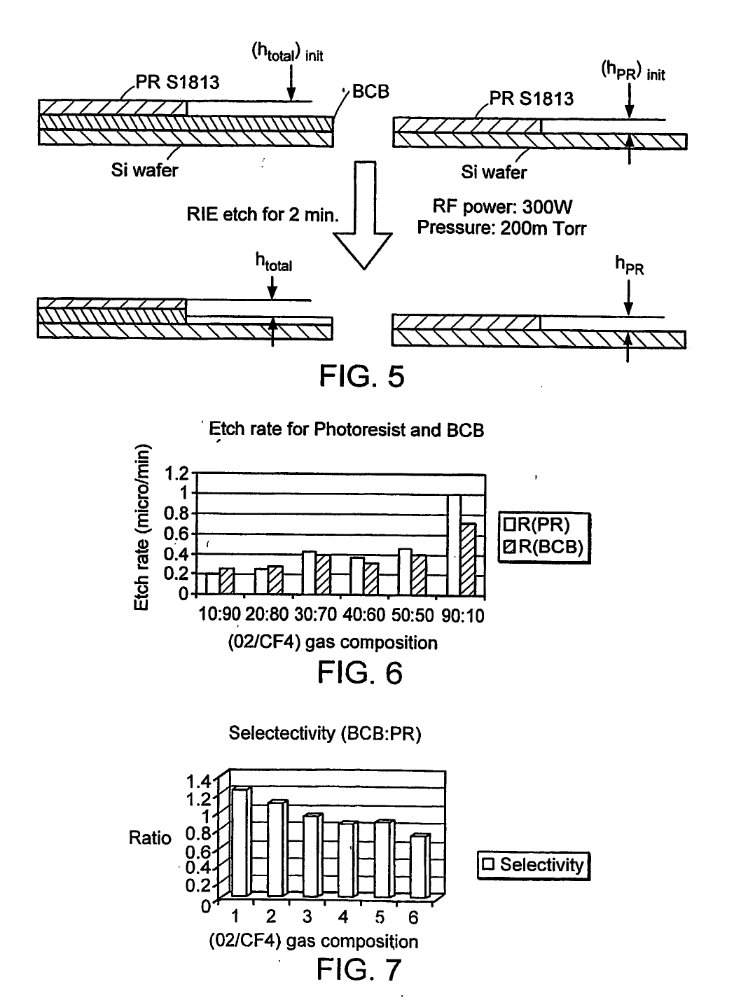

FIGS. 5, 6, and 7 show the experiment diagram, the etch rate, and selectivity results, respectively. The results indicate that a higher selectivity may be achieved for higher fluorine gas composition, but a higher etch rate may be achieved at higher oxygen concentrations. In our experiments, the initial layer thickness was 2 μm for PR and 2.4 μm for BCB. We therefore needed higher selectivity than that the one given by the high etch rate with 9:1 (O₂:CF₄) composition. A ratio of 5:5 gas composition was chosen to minimize the loss of BCB layer, and also provide a reasonably fast etch rate. The following equations show the etch rates for the BCB and PR layers that are shown in FIG. 5.

$${( {h}_{PR} )}_{init} - {h}_{PR} = a , \frac{a}{t} = {R}_{PR}$$

where t is the process time, R_{PR} is the photoresist etch rate.

$$\frac{{h}_{total} - \{ {( {h}_{total} )}_{init} - a \}}{t} = {R}_{BCB}$$

where R_{BCB} is the BCB etch rate, and the etch selectivity is given by:

$$\frac{{R}_{BCB}}{{R}_{PR}} = {S}^{BCB / PR}$$

As discussed above, after the BCB layer 206 has been patterned, the nitride/oxide layers 204 may be opened using dry-etch/BOE, and the bulk silicon wafer 202 may be etched using KOH or TMAH. Experiments that were undertaken to determine whether the BCB layer can survive this process step will now be described.

While BCB is highly resistant to chemical attack by most organic solvents, bases, and aqueous acids, the adhesion layer between BCB and substrate is particularly vulnerable. These adhesion problems were studied by comparing adhesion between BCB and Si with that between BCB and nitride or oxide. We also studied BCB loss (or delamination) in KOH and TMAH as a function of the level of curing prior to the wet-etch step. The adhesion strength might also be dependent on the type of adhesion promoter used.

In order to compare the etch resistance of the BCB film, eight different types of samples (labeled A-H) were fabricated and tested, as shown in Table 1, below.

TABLE 1
Sample preparation for etching

| | Adhesion | | | |
|---|---|---|---|---|
| Sample | Promoter | % curing | Substrate | Etchant |
| A | No | Soft | Si | KOH |
| B | Yes | Soft | Si | KOH |
| C | Yes | Soft | SiO₂ + Si | KOH |
| D | Yes | Soft | SiO₂ + Si | TMAH |
| E | Yes | Pre-baked | SiNₓ + Si | TMAH |
| F | Yes | Soft | SiNₓ + Si | TMAH |
| G | Yes | Hard | SiNₓ + Si | TMAH |
| H | Yes | Hard | Si | TMAH |

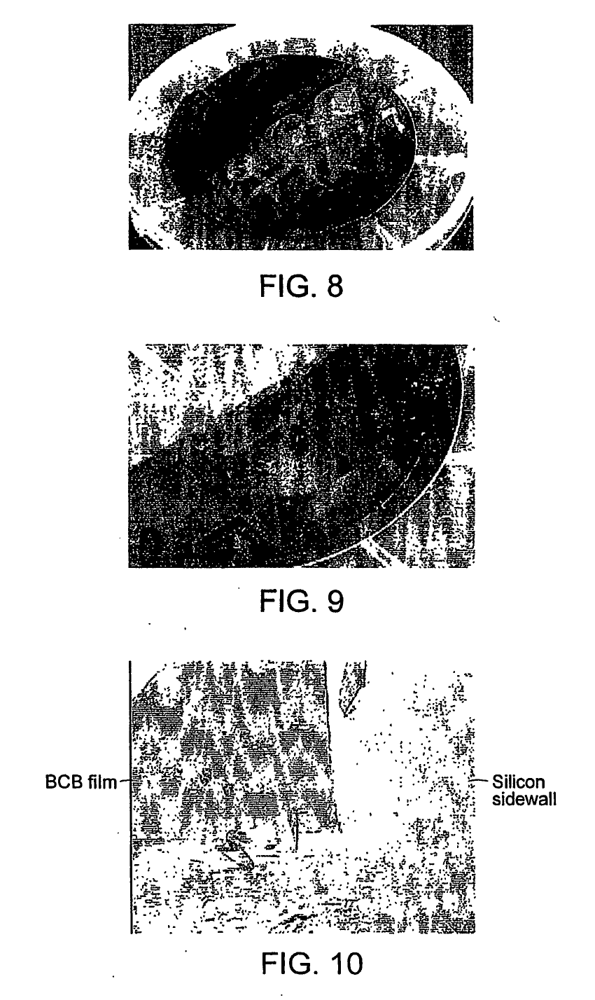

Samples A, B, and C were dipped into 45% KOH solution for 40 minutes and then inspected, while samples D, E, F, G, and H were dipped into 25% TMAH solution for up to 100 minutes. FIGS. 8, 9, and 10 show that inadequate adhesion between BCB and the substrate may cause delamination of BCB film in the KOH solution. While the BCB film etched much slower in KOH than the silicon substrate, the failure of BCB film occurred at the interface, and a BCB thin film residue was still present in solution after 40 minutes. We concluded that the higher etch rate for the substrate material, and the weaker the adhesion of BCB to the substrate, the shallower the sidewall definition will be. The observed delamination mechanism is illustrated in FIG. 11.

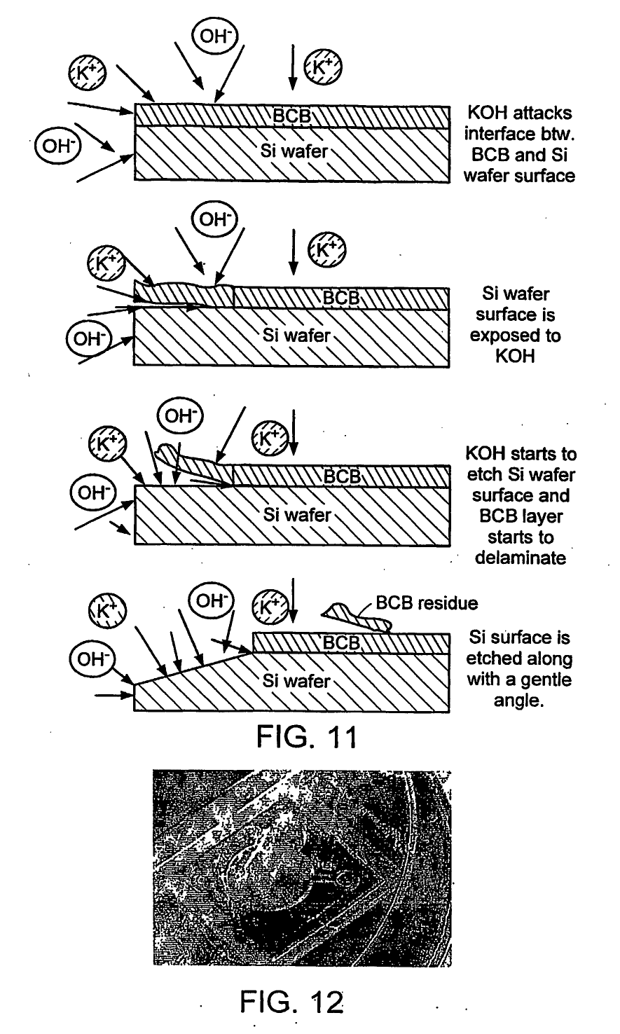

We expected that the penetration of KOH under the BCB film would be retarded if we used a substrate having a slower etch rate. The experiments were thus repeated with silicon dioxide (sample C). FIG. 12 shows the resulting KOH etched sample, where most of the BCB film remained on the mesa structures after 40 minutes. The experimental results also showed that the sidewall definition improved even further when TMAH was used for etching (sample D), and when a silicon nitride hard mask was used (sample F).

The etch selectivity SiO₂:Si is in the range 5000-7000:1 in TMAH and 300-1000:1 in KOH, depending on concentration. Both fully cured BCB and SiNₓ etch rates in KOH and TMAH are too small to be determined. After performing the previous experiments, we concluded that TMAH/KOH etching with a silicon nitride bottom layer for BCB provides the best result.

For samples E, F, and G, results showed that the partially cured BCB film did not survive the wet-etch whereas a fully cured layer did. Samples E and F were etched for 20 minutes in TMAH, while sample G was etched for 100 minutes. We measured the distance between the BCB film and the edge of silicon nitride to show the BCB film loss. The results are shown in Table 2 below.

TABLE 2
Etch conditions and the results for studying
the effect of curing on the BCB etch rate.

| | | Distance from BCB | |
|---|---|---|---|
| Sample | % of curing | to the wafer edge | TMAH etch time |
| E | Pre-baking | ˜1.3 mm | 20 min |
| F | Soft-cured | ˜400 micron | 20 min |
| G | Hard-cured | Not visually | 100 min |
| | | measurable with | |
| | | 5× magnification | |
| | | microscope | |

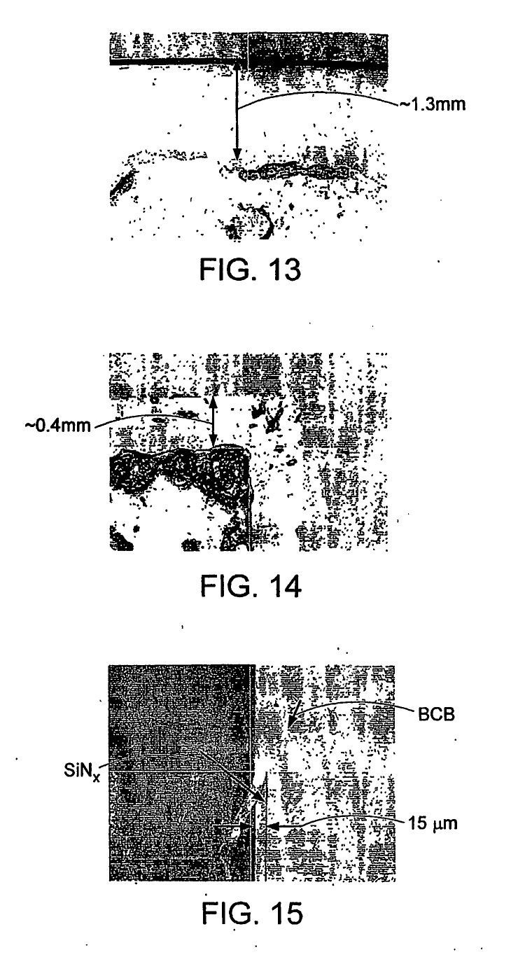

FIG. 13 shows sample E, which was pre-baked and TMAH etched for 20 minutes. FIG. 14 shows sample F, which was soft-cured and TMAH etched for 20 minutes. FIG. 15 shows sample G, which was hard-cured and TMAH etched for 100 minutes.

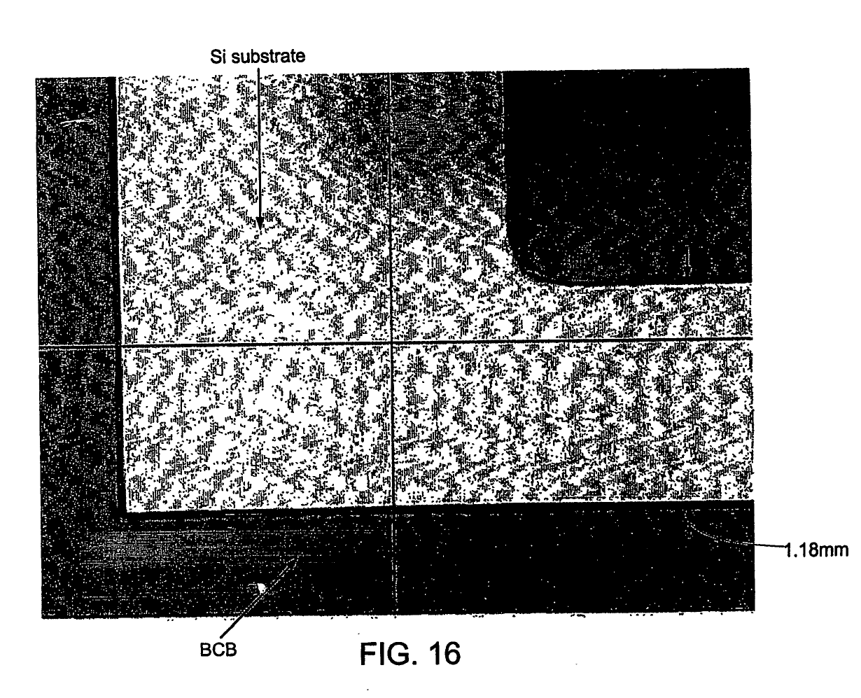

In FIG. 16, a 17 μm strip of BCB was removed by mechanical means, but a 5× magnification image did not allow the measurement of any BCB etch region after 100 minutes of etching in TMAH. We concluded that hard-cured BCB layers combined with bulk-micromachining in TMAH solution, were capable of transferring a BCB adhesive pattern on mesa structures at least 100 μm high, and with a feature resolution better than 1 μm.

As explained in (1) Niklaus, F., Enoksson, P., Kalvesten, E., and Stemme, G., 2001, “Low-temperature full wafer adhesive bonding,” Journal of Micromechanics and Microengineering 11, no. 2, and (2) Den Besten, C., van Hal, R. E. G., Munoz, J., and Bergveld, P., 1992, “Polymer bonding of micro-machined silicon structures,” Proceedings. IEEE Micro Electro Mechanical Systems. An Investigation of Micro Structures, Sensors, Actuators, Machines and Robots, New York, N.Y., USA: IEEE, xv+237, pp. 104-109, which are incorporated herein by reference in their entirety, using pre-baked BCB, flat wafers can be aligned and bonded at temperatures as low as 180 degrees celcius (° C.), and pressures greater than 1.7 bars. In some embodiments of the invention, however, it is preferable to bond wafers with a fully cured and patterned BCB layer because uncured BCB film would not likely survive during bulk micromachining.

A preliminary experiment failed to bond two wafers with fully cured patterned BCB at such a low temperature. This can be explained by the fact that uncured BCB provides more conformity and activation to the mated surface due to a lower glass transition temperature than that of fully cured BCB. The glass transition temperature for uncured BCB is very low and is strongly dependent on curing percentage. Therefore, it was expected that relatively high temperature (but not higher than 350° C.) and relatively high pressure was necessary to successful bonding of wafers with fully cured BCB mesa structures.

Preliminary bonding experiments were performed with “BCB/AP3000/Si” and “93CB/AP3000/SiNx/Si” samples processed in similar conditions to the samples G and H discussed above. In addition, another pair of wafers were bonded with pre-baked BCB on SiNx, which was not exposed to TMAH, for the purpose of comparison. The bonding was performed using the standard recipe for BCB bonding.

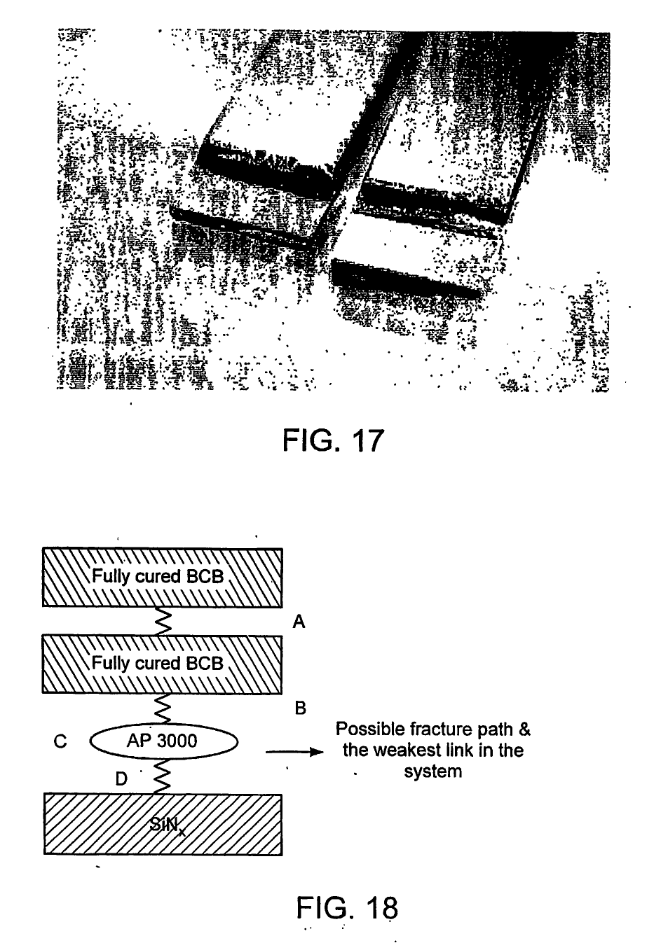

In all cases, a simple razor blade debonding test showed one of the mated surfaces appeared to have no BCB, as shown in FIG. 17. This seemed to suggest that the weakest interface was the adhesion promoter layer (see FIG. 18). A special technique, such as X-ray photoelectron spectroscopy (XPS), would have been necessary in order to identify the fractured layer. However, this was consistent with a result provided in Hohlfelder, R. J., Maidenberg, D. A., and Dauskardt, R. H., 2001, “Adhesion of Benzocyclobutene-passivated silicon in epoxy layered structures,” J. Master. Res., Vol. 16, No. 1, pp. 243˜255, where the interface fracture energy, “Gc,” was measured by double cantilever beam tests and ranged from 10 to 60 J/m² for the interface of BCB and SiNₓ with epoxy underfill. In addition, in Snodgrass, J. M., Pantelidis, D., Jenkins, M. L., Bravman, J. C., and Dauskardt, R. H., 2002, “Subcritical debonding of polymer/silica interfaces under monotonic and cyclic loading,” Acta Materialia 50, no. 9, (24 May 2002), pp. 2395-2411, the interface fracture energy for BCB/SiO₂ with AP3000 was measured to be below 21 J/m², by double cantilever beam tests.

Our experiments shown in Table 3 below using a four point bending test, indicate that the bond strength after the proposed recipe will be almost as good as the bond strength between flat wafers processed using the standard BCB recipe.

TABLE 3
Comparison of critical adhesion energy

| 3 Samples | Hard-cured BCB bonding | Normal BCB bonding |
|---|---|---|
| Critical adhesion | 27.4 | 30 |
| energy, G_{c} (J/m²) | | |
| Standard deviation | 2.95 | 0.9 |

It was explained above that BCB can be introduced in the bulk micromachining process before photolithography. In addition, plasma etch processing conditions for BCB with a range of CF₄:O₂ ratios, as well as silicon anisotropic etch results using a BCB layer as a wet etch-mask, were discussed. Although BCB is stable in most organic solvents and aqueous acids, soft-cured BCB showed layer delamination during silicon wet-etch in KOH and TMAH solutions with very shallow sidewall definition. The use of fully cured BCB may improve the channel quality, and a much better sidewall definition may be obtained by using additional inorganic layers such as silicon dioxide, or silicon nitride.

As an alternative to silicon, photo-etchable glasses may be used to micromachine channels. As described in T. R. Dietrich, W. Ehrfeld, M. Lacher, M. Kramer, B. Speit, “Fabrication technologies for Microsystems utilizing photoetchable glass,” Microelectronic Engineering, 30, pp. 497-504, 1996, which is incorporated herein by reference in its entirety, photo-etchable glasses are specially formulated glasses using a sensitizer (such as Ce+³) and a photosensitive metal (such as Ag⁺). Initially invented at Corning in the 1940's to add color in glass, various types of photo-etachable glass are commercialized at present by Mikroglas Technik AG under the brand name FOTURAN®. Such products are described, for example, in S. D. Stookey, “Photosensitve glass,” Industrial and Engineering Chemistry, 41, No. 4, pp. 856-861, 1949, and A. Freitag, D. Vogel, R. Scholz, T. R. Dietrich, “Microfluidic devices Made of Glass,” JALA, Journal of the Association for Laboratory Automation, 6, No. 4, pp. 45-49, 2001, which are incorporated herein by reference in their entirety.

This type of glass can be used to achieve 20:1 aspect ratio microstructures on up to 2 millimeter (mm) thick substrates. Even though the maximum feature resolution is only 25 μm, biocompatible microfluidic channels are relatively easy to fabricate using this glass. Because photo-etchable glasses have a low softening point (around 465° C.), they are not suited for high temperature bonding processes. Both low-temperature diffusion and anodic bonding can be used, but they require additional surface polishing.

As discussed below, BCB wafer bonding, integrated with deep-reactive-ion-etching (DRIE) for silicon, and HF etching for FOTURAN® glass are also viable methods to fabricate three-dimensional microfluidics. Instead of the common BCB bonding approach (e.g., micromachining on one wafer, spin-coating on the other wafer, bonding), BCB may be spin-coated and cured on a target wafer, prior to micromachining of the wafer. The BCB film may be patterned by dry-etching technique with a photoresist mask and the target wafer may then be bulk-micromachined together with the BCB mask. The two micromachined wafers may then be bonded together under vacuum or nitrogen gas environment, at low temperature.

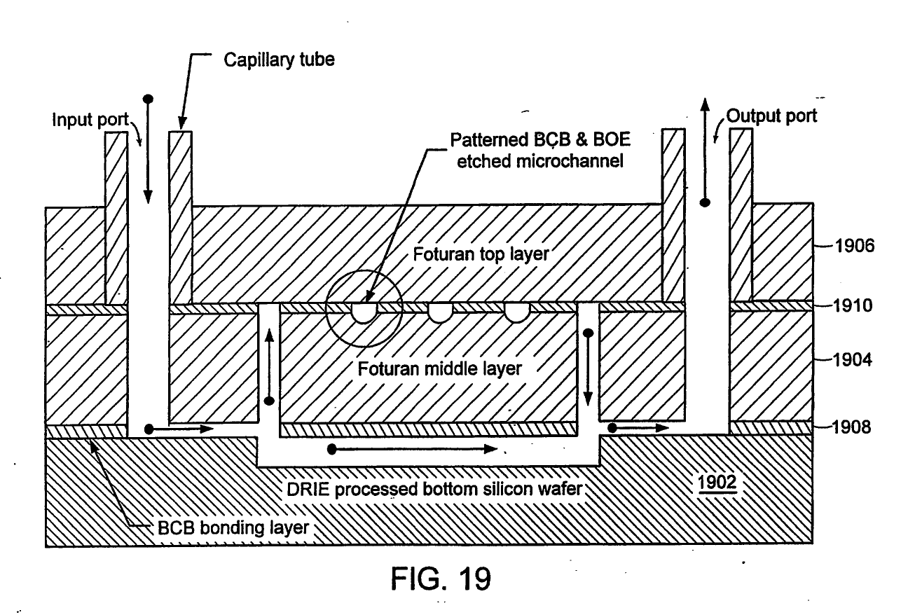

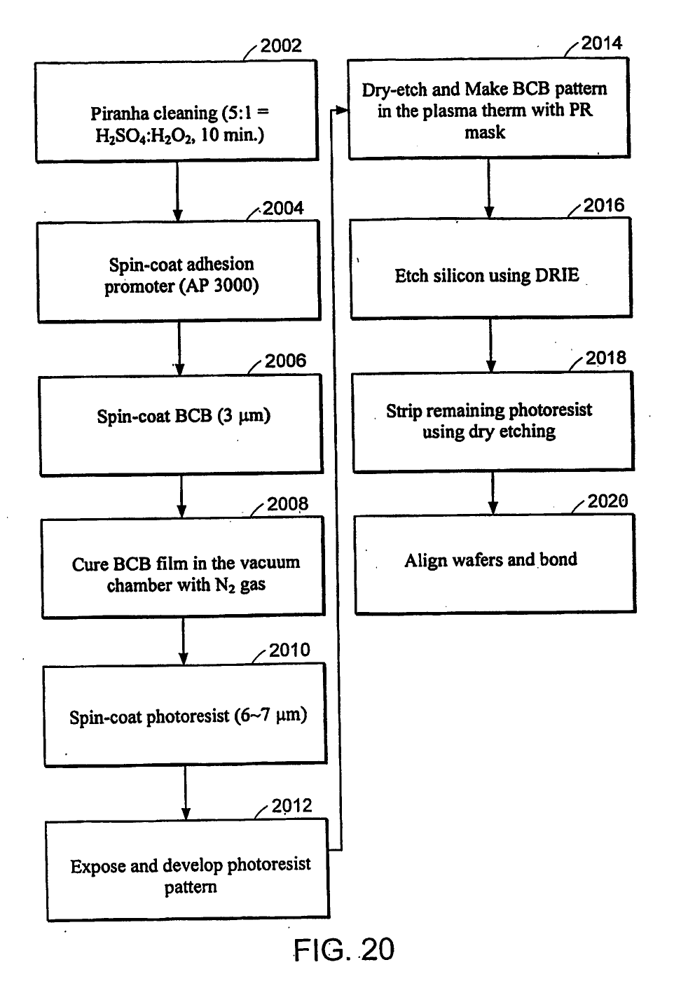

An illustrative example of a 3D microfluidic circuit that can be fabricated using BCB wafer bonding in silicon and glass is shown in FIG. 19. As shown, one or more of a silicon wafer 1902, a FOTURAN middle layer 1904, and a FOTURAN top layer 1906 may be micromachined after a BCB layer 1908, 1910 has been disposed on it, so as to form various ports, microchannels, etc., when the various wafers are bonded together via the BCB.

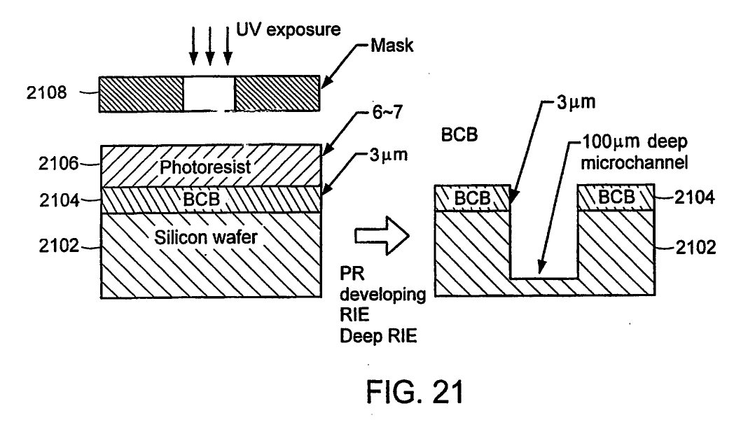

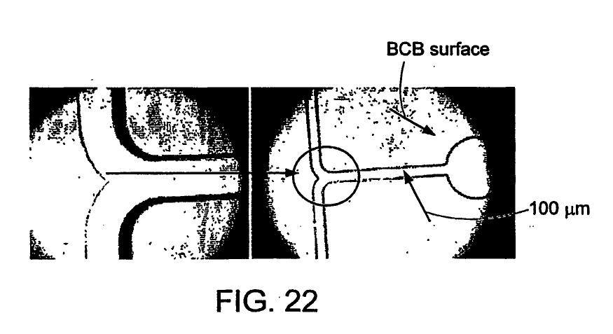

FIG. 20 is a flow chart illustrating various method steps that may be employed to micromachine a silicon wafer, after applying a BCB bonding layer, using dry etching techniques. FIG. 21 shows cross-sectional views of such a structure at two different stages during the process. The following description of the method of FIG. 21 will therefore reference the components shown in FIG. 22, as appropriate.

As shown, at step 2002, a silicon wafer 2102 may first be cleaned in Piranha solution, prior to spin coating, for organics removal. An adhesion promoter (e.g., AP3000) (not shown in FIG. 21) may then be applied (e.g., spin-coated) onto the cleaned wafer 2102 (step 2004), followed by the application (e.g., spin-coating) of a BCB layer 2104 (e.g., Dow, cyclotene 3022-46) of a particular thickness (e.g., 3 μm) (step 2006). The film thickness of the BCB may range, for example, from 2.4 μm to 5.8 μm at 1000˜5000 rpm.

The spin-coated BCB layer 2104 may then be partially or completely cured in a vacuum chamber with nitrogen gas to prevent oxidation of the BCB film (step 2008). A photoresist 2106 may then be applied (step 2010). A relatively thick photoresist (e.g., Shipley, STR 1045) may be selected so as to protect the BCB film 2104 during dry etching.

The photoresist layer 2106 may then be patterned (step 2012) and used for the purpose of soft masking for both RIE and DRIE etches (steps 2014, 2016). The BCB film 2104 may, for example, be patterned in a plasma therm using O₂/CF₄ gas mixture. Unless the bare silicon surface is exposed completely during the dry-etching process, the subsequent DRIE step may fail because BCB residue may prevent structuring of the silicon surface.

It may be difficult to determine when the silicon surface has been exposed at the end of dry etching because processing time will vary depending on pattern geometry, such as microchannel width or microreservoir area. Thus, it may be advisable to inspect the sample frequently (e.g., using a microscope) from the edge to the center of the wafer during dry etching. Microfluidic channels that are, for example, 100 μm deep, may be formed during the step 2016 by DRIE using Plasma therm ICP 770 based on Bosch fluorine process.

Since a thin photoresist layer may remain on the BCB layer 2104 after DRIE process, the remains photoresist layer 2106 can then be stripped by RIE (step 2018). Finally, another wafer (not shown, which may also have been micromachined to form a desired pattern, may be aligned with the processed wafer and bonded to it via the BCB layer 2104 (step 2020).

FIG. 21 shows each layer thickness before photoresist developing (left) and just prior to bonding (right). In this embodiment, it is important that the photoresist be thicker than sacrificial thickness on both RIE and DRIE. The etch selectivity between BCB and photoresist ranges from 0.7˜1 (PR/BCB) depending on the dry-etch gas concentration. The selectivity may be measured in the manner described above, and the etch rates may be used to calculate accurate sacrificial photoresist layer thickness. The type of photoresist used for sacrificial layer and the gas mixture ratio can significantly affect etch selectivity. Generally, DRIE shows a 50:1 (Si/PR) selectivity. FIG. 22 shows the excellent feature resolution for various microfluidic channels that may be obtained after DRIE and photoresist stripping on BCB.

Initially invented to add color in glass, as explained in S. D. Stookey, “Photosensitve glass,” Industrial and Engineering Chemistry, 41, No. 4, pp. 856-861, 1949, which is incorporated herein by reference in its entirety, photo-etchable glasses were found to provide a 20:1 etch selectivity of the UV exposed areas in 10% HF solution. Currently, the cost of FOTURAN wafers is high due to lower volume than silicon wafers, but the patterning process is extremely cost effective. While there are many formulations for FOTURAN, all are composed of a base glass, a sensitizer, and a photosensitive metal.

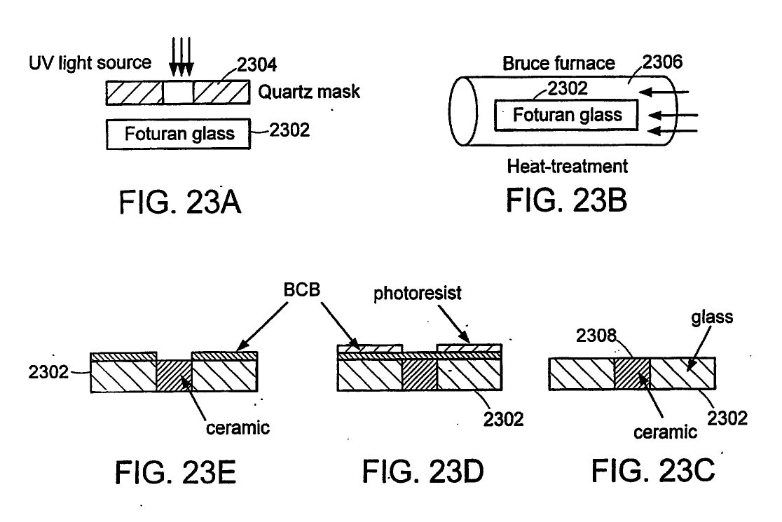

An illustrative example of a process for structuring FOTURAN glass is illustrated in FIGS. 23a-e. As shown in FIG. 23a, a FOTURAN glass wafer 2302 may be exposed through a chromium-patterned quartz mask 2304 using a collimated UV light source. The UV source may, for example, be a simple Dymax UV adhesive dispensing and curing system, providing enough energy in the 290-330 nanometer (nm) wavelength range after one hour. As shown in FIG. 23b, the exposed glass wafer 2302 may then heat-treated in a Bruce furnace 2306 using manufacturer's temperature vs. time recipe for 3 hours, after which the patterned area crystallizes into a brown ceramic 2308, as illustrated in FIG. 23c. Some surface warping and roughness may occur after heat-treatment, due to a different coefficient of thermal expansion (CTE mismatch) between glass 2302 and ceramic 2308. During the heat treatment, the silver atoms present in glass agglomerate to form bigger nuclei (at 500° C.). The glass crystallizes around the silver nuclei (at 600° C.) forming a ceramic. The crystal diameter is about 1˜10 μm. The formed crystals have a 20 times faster etch rates in 10% HF than regular glass (10-20 μm/min).

After HF etching, the surface may be planarized by chemical-mechanical polishing (CMP), and then diffusion may be used, for example, at 400° C. for 30 hrs, to perform wafer bonding. Instead, in order to avoid such a long bonding time, a BCB layer may be incorporated into the process. A short (e.g., 1-3 min) HF etch after heat treatment should produce a good enough FOTURAN glass surface to spin-coat BCB. The wafer may be soaked in Piranha solution for 10 minutes for organic removal, and BCB may be spin-coated on the surface with adhesion promoter. The BCB layer may then be fully cured by baking the wafers, for example, for one hour at 250° C. in nitrogen atmosphere.

Photoresist may then be spin-coated and developed in order to pattern the BCB layer using RIE, as shown in FIGS. 23d-e. The photoresist pattern should be carefully aligned with the original UV imprinted mask. This should be relatively easy to do due to the optical transparency of the BCB layer. The dry-etch step exposes the FOTURAN glass for the final 10% HF or BOE (buffer oxide etchant) solution. Through-wafer microchannels (500 μm deep) can be etched in only half an hour. Microchannels may be isotropically etched using BOE solution on the FOTURAN glass without destroying the BCB layer. However, BCB tends to delaminate in 10% HF solution within 20 minutes. In order to avoid BCB delamination, just like in the case of silicon etching with TMAH, a silicon nitride, or a metal mask such as sputtered Cr/Au may be incorporated in the process.

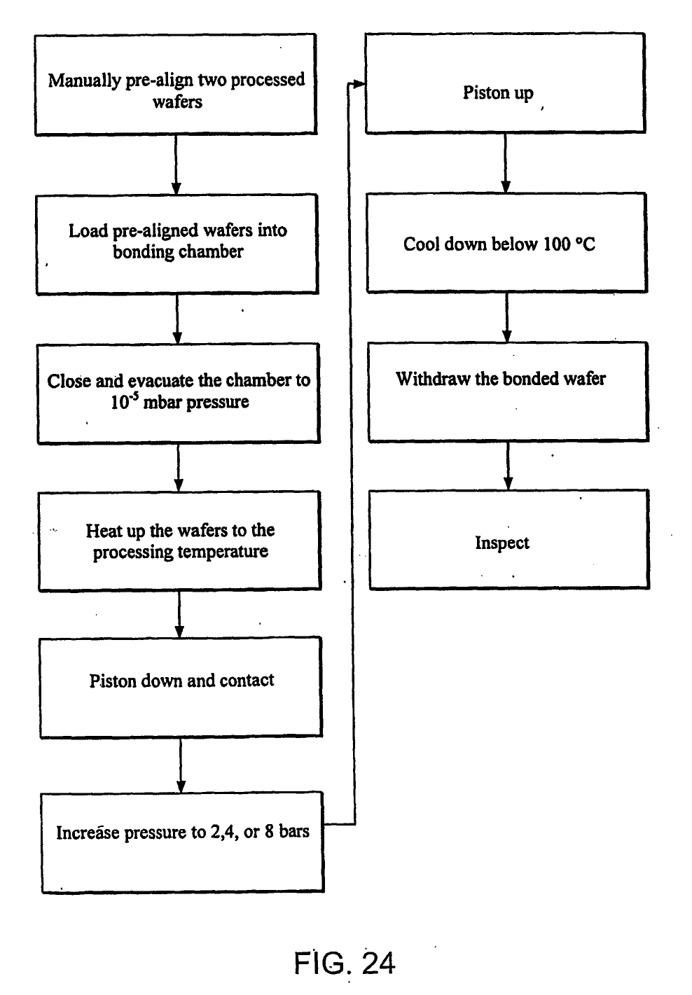

Bonding experiments were performed for both soft-cured and hard-cured BCB film in an EVG 520HE hot embossing system. In order to visually inspect the bonding quality, silicon wafers without pattern and Pyrex glass wafers were bonded together. Both silicon wafers and Pyrex wafers had identically processed hard-cured or soft-cured BCB film on their surfaces. Table 4 below shows all test sample sets for the bonding experiments, and the bonding process flow is shown in FIG. 24.

TABLE 4
Wafer sample set for bonding experiments

| Wafer A | Wafer B |
|---|---|
| Silicon wafer, hard-cured, 2 bar | Pyrex, hard-cured |
| Silicon wafer, hard-cured, 4 bar | Pyrex, hard-cured |
| Silicon wafer, hard-cured, 8 bar | Pyrex, hard-cured |
| Silicon wafer, soft-cured, 2 bar | Pyrex, soft-cured |
| Silicon wafer, deep RIE, soft-cured, 2 bar | Pyrex, soft-cured |

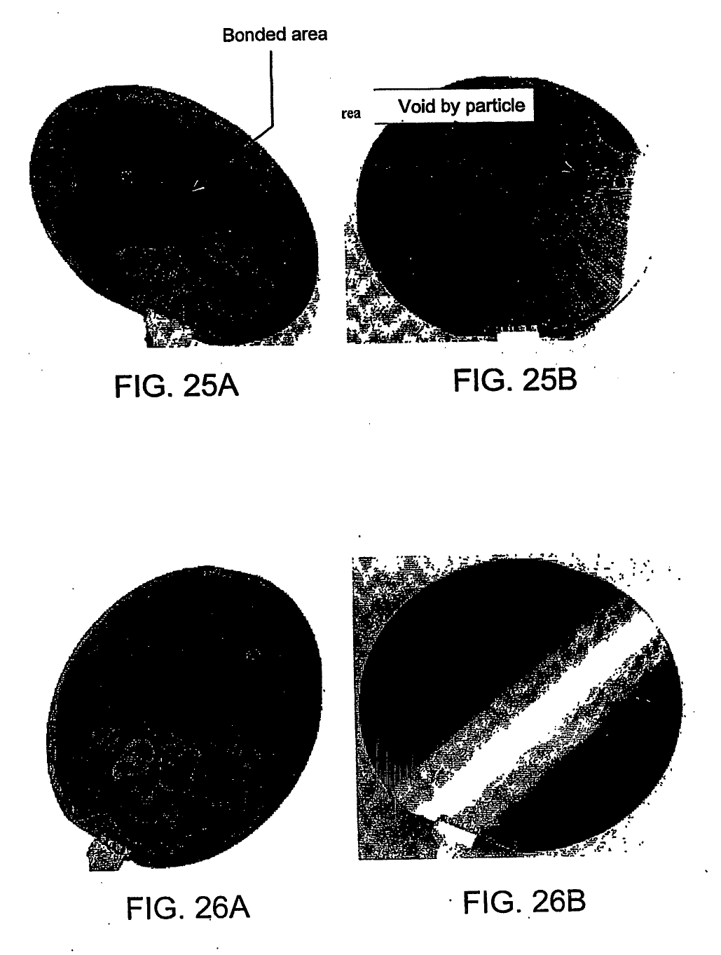

FIGS. 25a-b illustrate samples prepared by hard-cured BCB bonding at 2 bars and 4 bars, respectively. FIGS. 26a-b illustrate samples prepared by hard-cured BCB bonding at 8 bars and soft-cured BCB bonding at 2 bars, respectively.

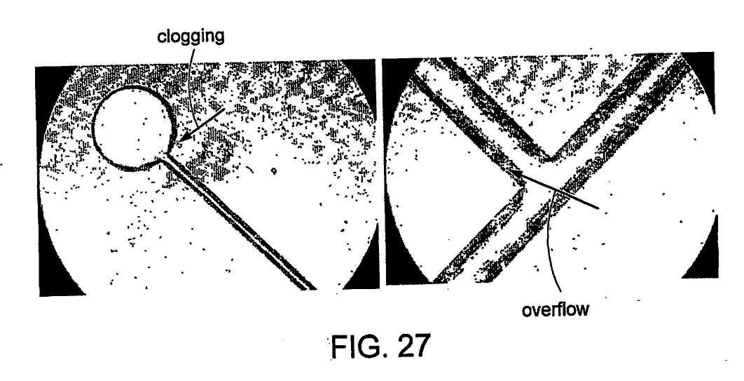

In the regular BCB bonding recipe, pressures of 1.7 bars were large enough to bond the wafers without voids. In our experiments, soft-cured BCB bonding at 2 bars also showed no voids, as shown in FIG. 26b. FIGS. 25a-b and 26a show hard-cured BCB bonding results as the bonding pressure increases from 2 bars to 8 bars. Unlike soft-cured BCB bonding, in this case an unbonded area and voids were found between each hard-cured bonding sample. As the bonding pressure increased, the unbonded area gradually diminished. Since the bonded area expanded from the center to the edge of the wafer, thickness variations of the cured BCB film appeared to be the main cause of unbonding. Also, voids created by particles trapped on the BCB surface were observed. This can explained by the fact that the fully cured BCB layer was less compliant and did not reflow as much as the soft-cured BCB to accommodate particles. FIG. 27 shows clogging of microchannels due to soft-cured BCB reflow over the microstructure edge. We concluded that even though hard-cured BCB bonding was more vulnerable to particle contamination than soft-cured BCB bonding and it required more bonding pressure, it was preferable as compared to soft-cured BCB because of this avoiding of reflow into the microchannels.

Having thus described several aspects of at least one embodiment of this invention, it is to be appreciated that various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A method for forming a microstructure, comprising steps of:
(a) applying a polymer substance to a first side of a first substrate;
(b) after performing the step (a), micromachining the first substrate from the first side to remove at least one portion of the first substrate; and
(c) after performing the step (b), adhering a second substrate to the first side of the first substrate via the polymer substance.

2. The method of claim 1, wherein the first substrate comprises a semiconductor wafer.

3. (canceled)

4. The method of claim 1, wherein the step (b) comprises a step of wet anisotropic etching the first substrate to remove the at least one portion of the first substrate.

5. The method of claim 4, further comprising a step of using the polymer substance as a wet etch mask during the step of wet anisotropic etching the first substrate.

6. The method of claim 4, wherein the step of wet anisotropic etching the first substrate comprises wet anisotropic etching the first substrate using an alkali-hydroxide solution.

7. The method of claim 6, wherein the alkali-hydroxide solution comprises potassium hydroxide (KOH).

8. The method of claim 4, wherein the step of wet anisotropic etching the first substrate comprises wet anisotropic etching the first substrate using a tetra methyl ammonium hydroxide (TMAH) solution.

9. The method of claim 1, wherein the step (b) comprises a step of dry etching the first substrate to remove the at least one portion of the first substrate.

10. (canceled)

11. The method of claim 9, wherein the step of dry etching the first substrate comprises deep-reactive-ion-etching the first substrate to remove the at least one portion of the first substrate.

12. The method of claim 1, wherein the first substrate comprises a glass material.

13. The method of claim 1, wherein the first substrate comprises a photo-etchable glass material.

14. (canceled)

15. The method of claim 1, wherein the step (b) comprises etching the first substrate using a hydrofluoric acid (HF) solution to remove the at least one portion of the first substrate.

16. The method of claim 1, further comprising a step of exposing the at least one portion of the first substrate to ultraviolet (UV) light so that crystals are formed in the at least one portion of the first substrate.

17. The method of claim 1, wherein the first substrate comprises a metal mask disposed on an underlying glass layer.

18. (canceled)

19. (canceled)

20. The method of claim 17, further comprising a step of sputtering the metal mask onto the underlying glass layer.

21. The method of claim 1, wherein the second substrate comprises a semiconductor wafer.

22. (canceled)

23. The method of claim 1, wherein the second substrate comprises a glass material.

24. (canceled)

25. The method of claim 1, wherein the first substrate comprises an oxide layer disposed on an underlying bulk layer.

26. (canceled)

27. The method of claim 25, further comprising a step of depositing the oxide layer on the underlying bulk layer using chemical vapor deposition (CVD).

28. The method of claim 25, further comprising a step of depositing the oxide layer on the underlying bulk layer using plasma enhanced chemical vapor deposition (PECVD).

29. The method of claim 1, wherein the first substrate comprises a nitride layer disposed on an underlying bulk layer.

30. (canceled)

31. The method of claim 29, further comprising a step of depositing the nitride layer on the underlying bulk layer using chemical vapor deposition (CVD).

32. The method of claim 29, further comprising a step of depositing the nitride layer on the underlying bulk layer using plasma enhanced chemical vapor deposition (PECVD).

33. (canceled)

34. The method of claim 1, wherein the polymer substance comprises benzocyclobutene (BCB).

35. The method of claim 1, further comprising a step of:
(d) etching the polymer substance to remove at least one portion of the polymer substance in a vicinity of the at least one portion of the first substrate.

36. The method of claim 35, wherein the step (d) comprises a step of dry etching the polymer substance to remove the at least one portion of the polymer substance.

37. (canceled)

38. The method of claim 36, wherein the step of dry etching the polymer substance comprises reactive-ion-etching (RIE) the polymer substance to remove the at least one portion of the polymer substance.

39. The method of claim 35, further comprising a step of using photolithography to create a mask for etching the polymer substance in accordance with the step (d).

40. The method of claim 1, wherein the step (a) comprises spin coating the polymer substance onto the first side of the first substrate.

41. The method of claim 1, further comprising a step of prebaking the polymer substance after performing the step (a).

42. The method of claim 1, further comprising a step of soft-curing the polymer substance after performing the step (a).

43. The method of claim 1, further comprising a step of hard-curing the polymer substance after performing the step (a).

44. The method of claim 1, wherein the step (c) comprises a step of fully curing the polymer substance when the second substrate is disposed on the polymer substance.

45. The method of claim 1, further comprising a step of disposing an adhesion promoter on the first side of the first substrate prior to performing the step (a).

46. The method of claim 45, wherein the step of disposing an adhesion promoter on the first substrate comprises spin-coating the adhesion promoter on the first side of the first substrate.

47. A device produced by the method of claim 1.
